(19) United States
(12) Patent Application Publication
(10) Pub. No.: US 2026/0293194 A1
(43) Pub. Date: Sep. 24, 2026

(54) P-TYPE REGION INTEGRATION FOR ENHANCED SQUARE-CELL SIC MOSFET

(71) Applicant: Renesas Electronics Corporation, Tokyo (JP)

(72) Inventors: Meng Chia LEE, Dallas, TX (US); Kijeong HAN, Morrisville, NC (US)

(73) Assignee: Renesas Electronics Corporation, Tokyo (JP)

(21) Appl. No.: 19/082,816

(22) Filed: Mar. 18, 2025

(51) Int. Cl. H10D 30/66; H10D 30/01; H10D 62/10; H10D 62/60; H10D 62/832; H10D 64/23

(52) U.S. Cl. CPC H10D 30/665; H10D 62/102; H10D 62/127; H10D 62/60; H10D 62/8325; H10D 64/252; H10D 30/0291

(57) ABSTRACT

A semiconductor structure includes a silicon carbide semiconductor substrate of a first conductivity type having an upper surface and a bottom surface. A plurality of unit cells is disposed on the upper surface of the semiconductor substrate, with each unit cell including a base region of a second conductivity type, and a source region of the first conductivity type disposed above the base region. A plurality of protective doped regions of the second conductivity type includes a first protective doped region located above the source region of each unit cell and a second protective doped region located at a corner portion of at least two adjacent unit cells such that the second protective doped region partially extends above the corner portion of the at least two adjacent unit cells for electrically connecting the base region of the two adjacent unit cells.

### BACKGROUND

The present disclosure generally relates to the field of semiconductor devices, and more particularly to planar silicon carbide metal-oxide-semiconductor field-effect transistors.

Silicon carbide (SiC) metal-oxide-semiconductor field-effect transistors (MOSFETs) are widely utilized in high-efficiency power conversion applications due to their superior electrical properties, including high breakdown voltage, low on-resistance, and fast switching speed. Compared to traditional silicon-based MOSFETs, SiC devices offer lower conduction and switching losses, making them ideal for high-power and high-frequency applications such as electric vehicles, industrial motor drives, and renewable energy systems. However, achieving optimal device performance requires careful design considerations to balance trade-offs between specific on-resistance (Rₛₚ), breakdown voltage, and reliability.

### SUMMARY

According to an embodiment of the present disclosure, a semiconductor structure includes a semiconductor substrate of a first conductivity type having an upper surface and a bottom surface, the semiconductor substrate including a silicon carbide substrate, a plurality of unit cells disposed on the upper surface of the semiconductor substrate, each unit cell including a base region of a second conductivity type, and a source region of the first conductivity type disposed above the base region, and a plurality of protective doped regions of the second conductivity type, with a first protective doped region located above the source region of each unit cell, and a second protective doped region located at a corner portion of at least two adjacent unit cells such that the second protective doped region partially extends above the corner portion of the at least two adjacent unit cells for electrically connecting the base region of the two adjacent unit cells.

According to another embodiment of the present disclosure, a semiconductor structure includes a semiconductor substrate of a first conductivity type having an upper surface and a bottom surface, the semiconductor substrate including a silicon carbide substrate, a plurality of unit cells disposed on the upper surface of the semiconductor substrate, each unit cell including a base region of a second conductivity type, and a source region of the first conductivity type disposed above the base region, and a plurality of protective doped regions of the second conductivity type positioned between at least two neighboring unit cells for electrically connecting the base region of each of the at least two neighboring unit cells.

According to yet another embodiment of the present disclosure, a semiconductor structure includes a semiconductor substrate of a first conductivity type having an upper surface and a bottom surface, the semiconductor substrate including a silicon carbide substrate, a plurality of unit cells disposed on the upper surface of the semiconductor substrate, each unit cell including a base region of a second conductivity type, and a source region of the first conductivity type disposed above the base region, and a plurality of protective doped regions of the second conductivity type extending laterally between adjacent base regions of neighboring unit cells to form a continuous protective network arranged in a geometric pattern.

### BRIEF DESCRIPTION OF THE DRAWINGS

The following detailed description, given by way of example and not intended to limit the embodiments described herein, will best be appreciated in conjunction with the accompanying drawings, in which:

FIG. 1 is a top-down view of a semiconductor structure illustrating components of a square-cell planar SiC MOSFET, according to an embodiment of the present disclosure;

FIG. 2 is a cross-sectional view of a unit cell of the semiconductor structure taken along line A-A′, according to an embodiment of the present disclosure;

FIG. 3 is a cross-sectional view of the unit cell taken along line B-B′, according to an embodiment of the present disclosure;

FIG. 4 is a top-down view of a semiconductor structure illustrating an alternate configuration of protective doped regions, according to an embodiment of the present disclosure;

FIG. 5 is a top-down view of the semiconductor structure illustrating an alternate configuration of the protective doped regions, according to an embodiment of the present disclosure;

FIG. 6 is a top-down view of a semiconductor structure illustrating an alternate configuration of protective doped regions, according to an embodiment of the present disclosure;

FIG. 7 is a top-down view of the semiconductor structure illustrating an alternate configuration of the protective doped regions, according to an embodiment of the present disclosure;

FIG. 8 is a top-down view of the semiconductor structure illustrating an alternate configuration of the protective doped regions, according to an embodiment of the present disclosure;

FIG. 9 is a top-down view of the semiconductor structure illustrating an alternate configuration of the protective doped regions, according to an embodiment of the present disclosure; and

FIG. 10 is a flowchart depicting operational steps for the fabrication of a semiconductor structure with protective doped regions, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

In the design of SiC planar MOSFETs, achieving low specific resistance (Rₛₚ) while maintaining reliable operation is a critical challenge. To improve channel density and reduce Rₛₚ, island cell structures have been introduced. However, these structures often create a weak spot at the center of the cell, which can lead to increased leakage currents and long-term reliability concerns.

A common approach to addressing this issue is the insertion of a P-type block at the weak spot to provide electrical shielding and reduce leakage. However, implementing a P-type region with a contact in the island cell can be challenging, particularly for fabrication processes that lack advanced lithographic capabilities. In such cases, the P-type region (P+) is often placed only at the center of the weak spot, limiting its effectiveness in mitigating leakage.

Another common solution involves blocking the junction field-effect transistor (JFET) implant in the weak spot area to prevent the formation of undepleted regions that contribute to leakage. However, this method introduces processing challenges due to the high energy required for JFET implantation. The use of a hard mask to selectively block implantation must be sufficiently thick to withstand high-energy processing, which complicates the fabrication process and may introduce additional manufacturing constraints.

Despite these existing solutions, achieving an optimal balance between specific resistance, leakage suppression, and manufacturability remains a challenge. There is a need for an improved design and process integration that effectively addresses these issues while maintaining compatibility with existing fabrication techniques.

Therefore, embodiments of the present disclosure provide a planar SiC MOSFET with a P-type plug square-cell design that addresses the aforementioned challenges by incorporating P-type protective doped regions, which may include P+ regions or P-base regions, adjacent to P-base (or P-well) regions of the semiconductor device. Specifically, the proposed P-type protective doped regions are formed such that they can be electrically connected to an adjacent P-base region, preventing it from floating and ensuring stable operation. This P-plug protection approach can be suitable for narrower cell pitch designs, offering improved electrical performance and reliability. Unlike traditional designs where a high-doping P+ region is placed in the cell center with a contact, the proposed cell structure eliminates the need for direct contact on the central P+ region.

Additionally, the proposed P-type protected cell design can reduce gate-to-drain capacitance (C_{gd}) through shielding effects, improving switching speed and lowering energy losses. As a result, the proposed embodiments can optimize switching performance while enhancing the reliability and efficiency of SiC planar MOSFETs in high-performance power electronics applications. Furthermore, the proposed design remains compatible with both advanced and traditional fabrication techniques, ensuring practical implementation across various manufacturing processes.

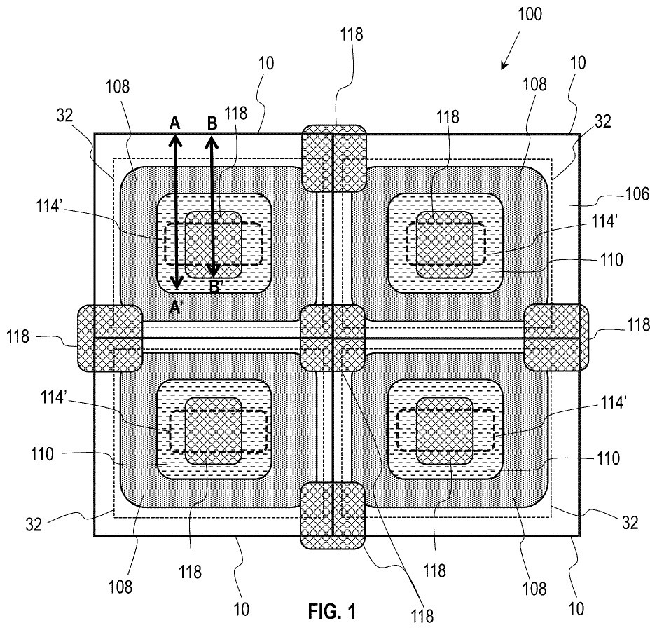

Embodiments by which the P-type protective regions for square-cell planar SiC MOSFETs can be formed are described in detail below by referring to the accompanying drawings in FIGS. 1-10.

FIG. 1 is a top-down view of a semiconductor structure 100 illustrating components of a square-cell planar SiC MOSFET, according to an embodiment of the present disclosure.

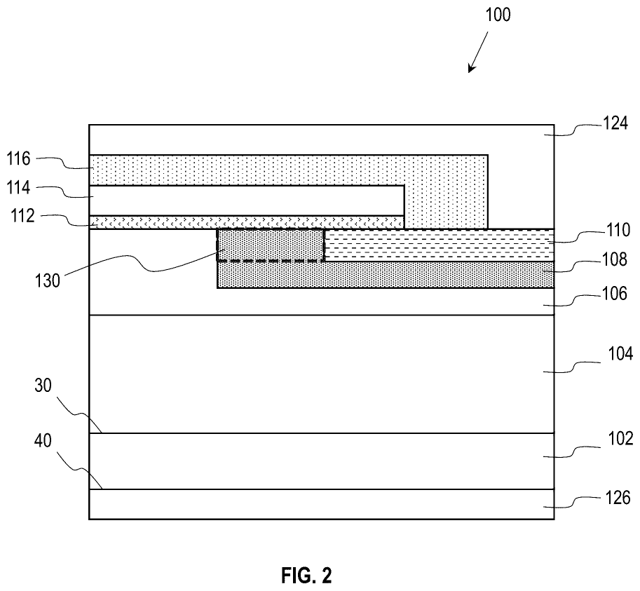

FIG. 2 is a cross-sectional view of a unit cell 10 of the semiconductor structure 100 taken along line A-A′, according to an embodiment of the present disclosure.

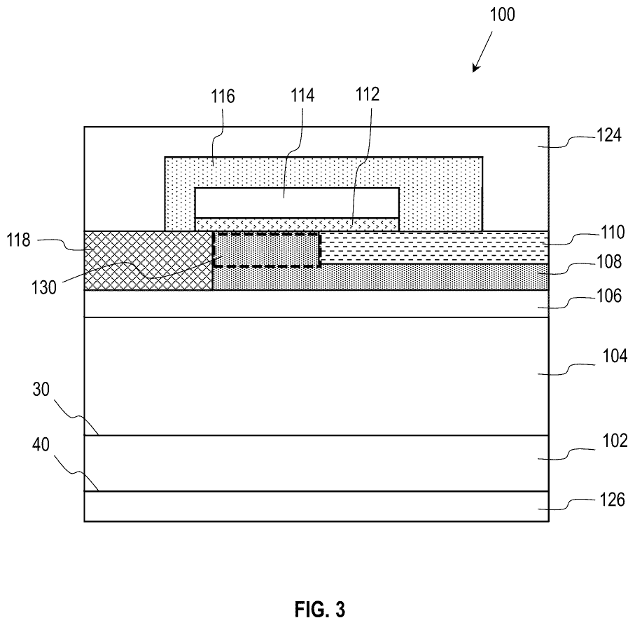

FIG. 3 is a cross-sectional view of the unit cell 10 taken along line B-B′, according to an embodiment of the present disclosure.

With reference now to FIGS. 1-3 simultaneously, the semiconductor structure 100 includes a semiconductor substrate (hereinafter “substrate”) 102 of a first conductivity type made of silicon carbide (SiC). A thickness of the initial substrate 102 is approximately 350 μm. The substrate 102 can be grinded to approximately 100 mm during backside processing steps. The impurity concentration in the substrate 102 can vary between approximately 1×10¹⁸ cm⁻³ to approximately 1×10¹⁹ cm⁻³. The first conductivity type can be P-type or N-type. In this embodiment, the first conductivity type is N-type.

It should be noted that substrate 102 serves as a drain region for the semiconductor structure 100, providing a pathway for current flow. While the drain region is integrated within the substrate 102, in some embodiments it can be engineered with distinct doping characteristics or other modifications to meet specific designs, enhance performance or manage thermal properties. Substrate 102 further includes an upper surface 30 and a bottom surface 40, as depicted in FIGS. 2-3.

According to an embodiment, the semiconductor structure 100 includes a plurality of unit cells (hereinafter “unit cells”) 10 arranged on the upper surface 30 of the substrate 102. Each unit cell 10 includes a transistor region 32 that facilitates current conduction and switching operations. For ease of illustration, only four unit cells 10, each with a corresponding transistor region 32, are depicted in the figures. However, it should be noted that the semiconductor structure 100 may include any number of unit cells 10 with corresponding transistor regions 32, as required by design specifications.

A drift layer 104 of the first conductivity type is formed on the upper surface 30 of the substrate 102. The drift layer 104 is made of silicon carbide with an added impurity concentration that is lower than the impurity concentration of substrate 102. In general, drift layer 104 can be formed by epitaxial growth by using the semiconductor substrate 102 as seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In some embodiments, drift layer 104 can be formed by chemical vapor deposition (CVD) of the semiconductor material (i.e., SiC).

A thickness of the drift layer 104 is determined by the device voltage rating. For example, the thickness of the drift layer 104 can be approximately 10 μm for 1.2 kV rated devices. The impurity concentration of the drift layer 104 can be approximately 1×10¹⁶ cm⁻³ for 1.2 kV rated devices. However, the impurity concentration of the drift layer 104 is not limited to this value and may be in a range of approximately 1×10¹⁴ cm⁻³ to approximately 1×10¹⁷ cm⁻³ depending on the device voltage rating.

According to an embodiment, each transistor region 32 of an unit cell 10 further includes a junction field effect transistor (JFET) region 106, a base region 108 formed above the JFET region 106, a source region 110 formed above the base region 108, a gate oxide 112 formed above and in contact with JFET region 106, base region 108 and source region 110, a gate electrode 114 formed above the gate oxide 112, an interlevel dielectric layer 116 formed above the gate electrode, and a top metal layer 124 formed above the interlevel dielectric layer 116 in at least partial contact with source region 110. In an embodiment, each unit cell 10 further includes doped regions 118, as depicted in FIG. 1 and FIG. 3.

With continued reference to FIGS. 1-3, the JFET region 106 is formed above and in contact with the drift layer 104. In some instances, JFET region 106 can be formed with a higher donor doping of the first conductivity type that can vary between approximately 1×10¹⁵ cm⁻³ and approximately 1×10¹⁸ cm⁻³. A thickness of the JFET region 106 is approximately 0.1 μm to approximately 3.5 μm.

The base region 108 includes a doped semiconductor region of a second conductivity type formed above the JFET region 106. A thickness of the base region 108 is approximately 0.1 μm to approximately 1.0 μm. The impurity concentration of the base region 108 can vary between approximately 1×10¹⁹ cm⁻³ to approximately 1×10²¹ cm⁻³. The second conductivity type can be P-type or N-type. Generally, the second conductivity type is opposite to the first conductivity type. Thus, in this embodiment, the second conductivity type is P-type. In an embodiment, a channel region 130 of the second conductivity type is formed within base region 108. Channel region 130 is disposed above and in contact with JFET region 106 and adjacent to source region 110 and doped region 118.

The source region 110 is formed above and in contact with the base region 108. A thickness of the source region 110 is approximately 0.1 μm to approximately 0.5 μm. Source region 110 may include a heavily-doped semiconductor layer of the first conductivity type. A dopant concentration of source region 110 can vary, for example, between 1×10¹⁹ cm⁻³ and 1×10²¹ cm⁻³.

In one or more embodiments, varying impurity or dopant concentrations across the different regions of semiconductor structure 100 can be attained through ion implantation or the diffusion of impurity ions or dopants. For example, in embodiments in which the first conductivity type is N-type and the second conductivity type is P-type, N-type dopants such as phosphorus (P) or arsenic (As) can be implanted into different regions of semiconductor structure 100 to form N-type doped semiconductor regions, while P-type dopants such as boron (B), aluminum (Al) or gallium (Ga) can be implanted into different regions of semiconductor structure 100 to form the P-type doped semiconductor layers.

With continued reference to FIGS. 1-3, doped regions 118 can be formed at different locations within semiconductor structure 100. As shown in the cross-sectional view of FIG. 3, doped regions 118 can be formed above and in contact with JFET region 106 and adjacent to base region 108. Additionally, doped regions 118 can be formed above source regions 110 and at corners of each unit cell 10. Specifically, doped regions 118 located at the corners of each unit cell 10 can extend over a corner portion of the base region 108 of one unit cell 10 and a corresponding corner portion of an adjacent unit cell 10 for electrically connecting base regions 108 of the adjacent unit cells 10.

Each doped region 118 includes a semiconductor region composed of a heavily doped silicon carbide layer of the second conductivity type. An ion implantation process can be conducted on the semiconductor structure 100 to form doped regions 118. Doped regions 118 can be formed with an impurity concentration of the second conductivity type varying between approximately 1×10¹⁹ cm⁻³ and approximately 1×10²¹ cm⁻³. In embodiments in which the second conductivity type is P-type, doped region 118 can be referred to as P+ region. A thickness of the doped regions 118 can vary between approximately 0.1 μm and approximately 3.5 μm, depending on design requirements. In an embodiment, doped regions 118 may include a quadrilateral shape.

As illustrated in FIG. 1, doped regions 118 formed at corners of each unit cell 10 and partially extending above corner portions of the base region 108 create island-like protective regions within semiconductor structure 100. These protective doped regions 118 at the cell corners may help mitigate electric field concentrations in these areas of the semiconductor structure 100, thereby enhancing device reliability. Additionally, the shielding effect of the protective doped regions 118 may reduce the gate-drain capacitance (C_{gd}), which enhances switching speed and decreases energy losses.

It should be noted that the proposed semiconductor structure 100 is designed to accommodate narrower cell pitch configurations while ensuring stable electrical operation. In the proposed design, P-type protective doped regions 118, which can include P+ or P-base regions, are strategically positioned within each unit cell 10. The doped region 118 at the center of each unit cell 10 does not have a direct electrical contact but is electrically connected to the adjacent base region 108. This prevents floating and maintains a well-defined potential distribution, enhancing device performance by mitigating unwanted charge buildup and improving reliability. While in the described embodiments the doped regions 118 include a high-doping P+ region, the proposed design is not limited to P+ and can include any P-type doping concentration, such as P-base, to achieve the desired electrical characteristics.

With continued reference to FIGS. 1-3, the gate oxide 112 can be formed above doped region 118, base region 108 and source region 110 using various types of deposition processes. The gate oxide 112 can electrically separate a subsequently formed gate electrode from active areas of the semiconductor structure 100. In one or more embodiments, gate oxide 112 can be formed by conformal deposition of a gate insulating film. Non-limiting examples of gate insulating films to form gate oxide 112 can include silicon dioxide (SiO₂), silicon nitride (Si₃N₄), aluminum oxide (Al₂O₃), lanthanum oxide (La₂O₃), zirconium dioxide (ZrO₂), tantalum oxide (Ta₂O₅), hafnium oxide (HfO₂) and the like. In an exemplary embodiment, a thickness of the gate oxide 112 can vary between approximately 10 nm to approximately 100 nm.

The process of forming gate electrode 114 usually includes depositing a conductive material, such as polysilicon, above the gate oxide 112. The gate electrode 114 and gate oxide 112 provide a gate structure for the semiconductor structure 100. Gate electrode 114 can be positioned on a center portion of each cell unit 10 as depicted by projection line 114′ in FIG. 1.

After forming the gate electrode 114, interlevel dielectric layer 116 can be formed to fill voids and electrically isolate active regions within the semiconductor structure 100. The interlevel dielectric layer 116 is disposed above the gate electrode 114. More particularly, the interlevel dielectric layer 116, as depicted in FIGS. 2 and 3, covers an upper surface and opposite sidewalls of gate electrode 114, opposite sidewalls of gate oxide 112, and partially covers an upper surface of doped region 118 and source region 110. In one or more embodiments, the interlevel dielectric layer 116 can be formed by, for example, conformal deposition (e.g., CVD) of a dielectric material such as silicon oxide, silicon nitride, and the like. In one or more embodiments, a patterning process can be conducted on the interlevel dielectric layer 116 to achieve the shape shown in the figures.

In an embodiment, a top metal layer 124 is deposited above the interlevel dielectric layer 116 and above exposed portions of source region 110 and doped region 118, as shown in FIGS. 2-3. The top metal layer 124 provides a source terminal or source electrode that electrically contacts source region 110 and doped region 118.

A bottom metal layer 126 can be formed on the bottom surface 40 of the substrate 102. The bottom metal layer 126 serves as a drain terminal or drain electrode that provides electrical (ohmic) contact with substrate 102.

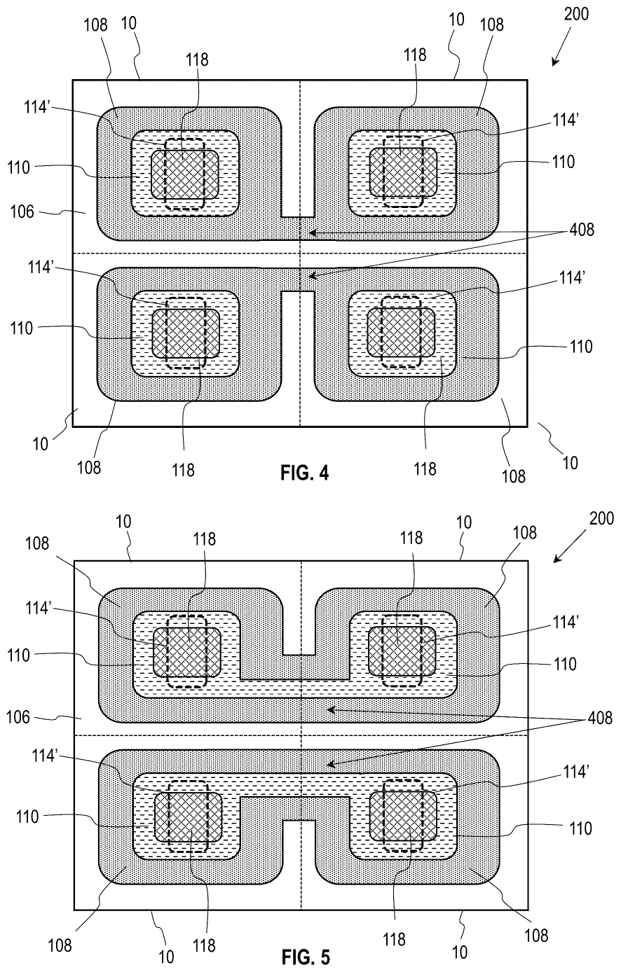

With reference now to FIG. 4 and FIG. 5, simultaneously, top-down views of a semiconductor structure 200 illustrating alternate configurations of first protective doped regions 408 are shown, according to an embodiment of the present disclosure. The description of FIGS. 4-5 can refer to components shown in FIGS. 1-3 above. It should be noted that, in this embodiment, components of the semiconductor structure 200 are substantially the same as those of semiconductor structure 100. Accordingly, for ease of illustration and description, the same reference numerals will be used to denote corresponding elements in the alternate embodiments.

The embodiments of FIGS. 4-5 illustrate variations in the formation of P-type first protective doped regions 408, which are defined by the patterning and implantation processes associated with the P-base mask. More particularly, the P-base mask is employed in photolithographic and ion implantation steps to define the base regions 108 within the semiconductor structure 200. By modifying the mask pattern or adjusting the implantation conditions, additional P-type first protective doped regions 408, such as P+ regions, P-islands, or P-type shielding structures, can be formed without requiring additional lithography steps. These variations allow for enhanced device performance by mitigating electric field concentrations, reducing gate-drain capacitance (C_{gd}), and improving overall reliability.

In the embodiment illustrated in FIG. 4, the P-base mask is modified to form protective doped regions 408. In this configuration, the protective doped regions 408 represent an extension of the base region 108 that effectively connect base regions 108 of two contiguous unit cells 10. Stated differently, the first protective doped regions 408 are positioned between adjacent bottom corners of two neighboring unit cells 10, thereby establishing an electrical connection between their respective base regions 108. While the doped regions 118 shown in FIG. 1 are highly doped P-type regions (i.e., P+ regions) located at the corners of each unit cell 10, this embodiment instead forms P-type first protective doped regions 408 as an extension of the base region 108 through modifications to the P-base mask. This structural variation not only provides electrical continuity between adjacent base regions 108 but also prevents floating effects, ensuring stable operation of the semiconductor structure 200. In an embodiment, a thickness of the first protective doped regions 408 may be approximately 1.2 mm.

It should be noted that due to the self-aligned process, if the P-base mask is wider than approximately 1 μm, source regions 110 may form within the base regions 108 (i.e., P-base) and first protective doped regions 408, as illustrated in FIG. 5.

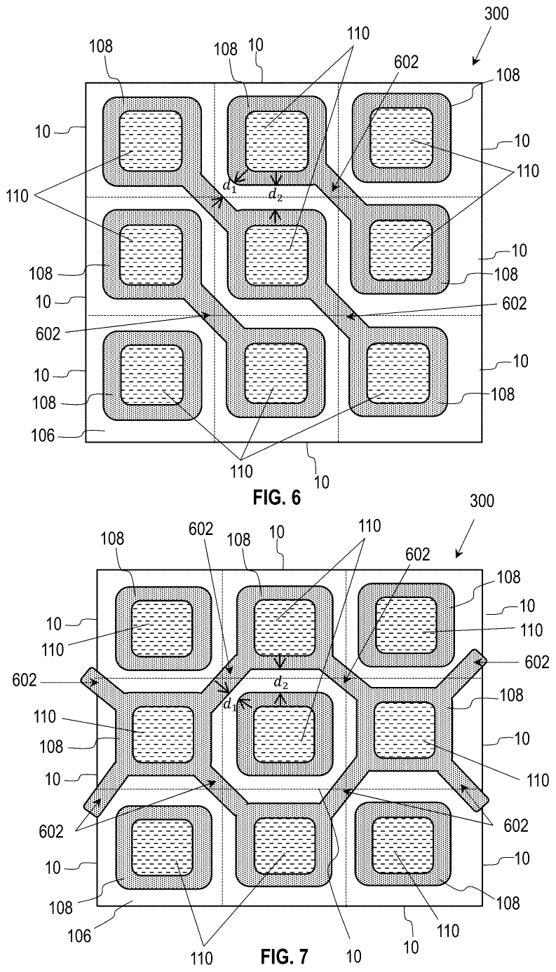

With reference now to FIGS. 6-9, simultaneously, top-down views of a semiconductor structure 300 illustrating alternate configurations of second protective doped regions 602 are shown, according to an embodiment of the present disclosure. The description of FIGS. 6-9 can refer to components shown in FIGS. 1-5 above. It should be noted that, in this embodiment, components of the semiconductor structure 300 are substantially the same as those of semiconductor structure 100. Accordingly, for ease of illustration and description, the same reference numerals will be used to denote corresponding elements in the alternate embodiments.

The embodiments depicted in FIGS. 6-9 illustrate variations in the formation of P-type protective regions, referred to as second protective doped regions 602. Similar to the first protective doped regions 408, the second protective doped regions 602 are defined through the patterning and implantation processes associated with the P-base mask. Accordingly, by modifying the pattern of the P-base mask, additional P-type second protective doped regions 602 can be incorporated into semiconductor structure 300 without needing additional lithography steps. For illustration purposes only, without intent of limitation, these embodiments depict semiconductor structure 300 as including nine unit cells 10.

The different configurations of second protective doped regions 602 depicted in FIGS. 6-9 are designed to optimize device performance by shielding high electric fields, mitigating premature short-circuit failures, and reducing gate-to-drain capacitance (C_{gd}). By strategically modifying the placement and formation of the second protective doped regions 602, each embodiment provides an approach to enhancing the robustness, switching efficiency, and overall reliability of the SiC MOSFET while maintaining compatibility with advanced and traditional fabrication techniques.

In the embodiment shown in FIG. 6, the second protective doped regions 602 are configured to laterally connect corner portions of the base regions 108 of unit cells 10 that are positioned diagonally relative to each other. The second protective doped regions 602 extend between adjacent unit cells 10, forming a continuous connection that enhances electric field shielding and improves device reliability. In an embodiment, a thickness of the second protective doped regions 602 may be approximately 1.2 mm.

In this embodiment, first distance d₁ represents a diagonal spacing between a second protective doped region 602 and a corner portion of the base region 108 of a neighboring unit cell 10, while second distance d₂ represents a vertical spacing between the base regions 108 of two adjacent unit cells 10. In an embodiment, the first distance d₁ is less than the second distance d₂. The condition d₁≤d₂ may ensure that the protective structure effectively mitigates high electric field concentrations and optimizes charge distribution within the semiconductor structure 300. In an embodiment, the first distance d₁ may vary between approximately 0 mm and 1.4 mm, while the second distance d₂ may vary between 0.8 mm to 1.4 mm. In general, the first distance d₁ is smaller than the second distance d₂, and more specifically, at least 10% shorter or narrower than the second distance d₂.

In the embodiment shown in FIG. 7, the second protective doped regions 602 are configured to extend outwards from corner portions of the base regions 108 of unit cells 10, forming a branched or star-like interconnection pattern. Unlike the embodiment of FIG. 6, where the second protective doped regions 602 primarily establish diagonal connections between adjacent unit cells 10, this configuration integrates additional lateral extensions that connect multiple neighboring base regions 108. Additionally, the arrangement of the second protective doped regions 602 in this embodiment forms an octagonal structure around a unit cell 10 located at the center of the semiconductor structure 100. The octagonal structure encloses the central unit cell 10. This octagonal structure may result from the interconnection of the extended branches of the second protective doped regions 602, which emanate from the corner portions of the base regions 108 of adjacent unit cells 10.

Accordingly, the extended structure of the second protective doped regions 602 provides enhanced electric field shielding and more effective charge distribution across the semiconductor structure 300. By forming continuous paths between adjacent unit cells 10, this configuration can further mitigate premature short-circuit failures and optimize device reliability while also reducing parasitic capacitances such as C_{gd}.

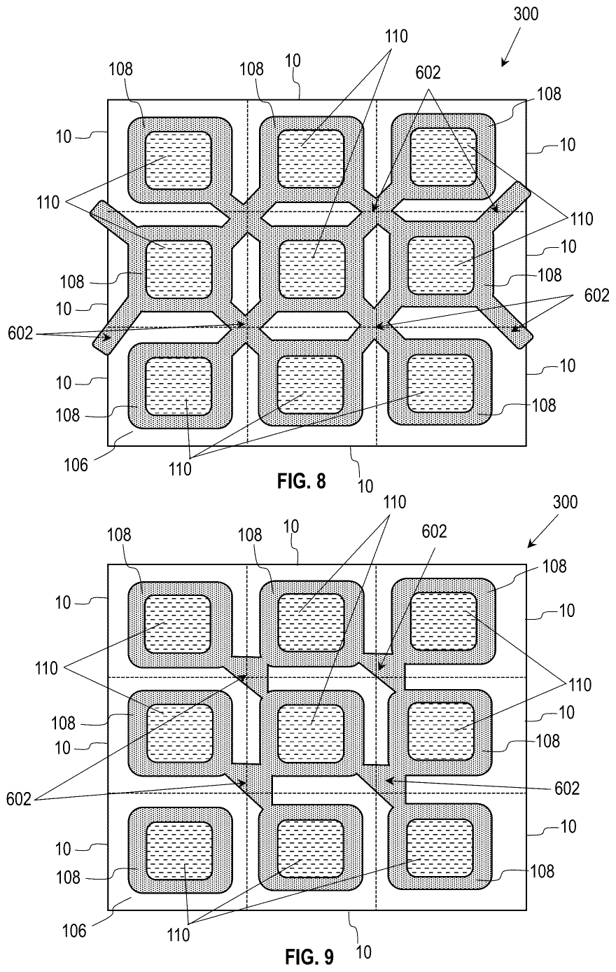

In the embodiment illustrated in FIG. 8, the second protective doped regions 602 form a continuous interconnection network that extends both laterally and diagonally between adjacent unit cells 10. Unlike the previous embodiments, where the second protective doped regions 602 were primarily configured to connect specific corners of neighboring base regions 108, this configuration introduces a more integrated structure. In this embodiment, at the center of four adjacent unit cells 10, the second protective doped regions 602 enclose an octagonal structure that surrounds a source region 110 of a central unit cell 10. This configuration provides enhanced shielding of the high electric field at the junctions between neighboring unit cells 10, further mitigating premature short-circuit failures and contributing to improved device robustness. The formation of second protective doped regions 602 in this embodiment, similar to previous ones, can be achieved through modifications to the P-base mask pattern.

In the embodiment illustrated in FIG. 9, the second protective doped regions 602 are configured with a triangular geometry, with each vertex or corner of the triangle connecting to a corner portion of the base regions 108 of three adjacent unit cells 10. This arrangement forms a continuous network of triangular protective regions, which are strategically positioned between groups of adjacent unit cells 10 to optimize electric field shielding. In this embodiment, the triangular configuration of the second protective doped regions 602 enhances the interconnection between adjacent unit cells, ensuring robust electrical continuity and preventing floating of the base regions 108. This design may also improve electric field distribution and mitigates high-field concentrations at the corners of the base regions 108, thereby reducing the likelihood of premature short-circuit failures. As in prior embodiments, the second protective doped regions 602, as depicted in FIG. 9, can be formed by modifying the pattern of the P-base mask, allowing for the integration of these features without requiring additional lithographic steps.

The previously described embodiments provide an efficient and reliable approach to enhancing device robustness while maintaining compatibility with existing fabrication techniques. In the embodiments illustrated in FIGS. 6-9, the condition d₁≤d₂, representing the relationship between the vertical spacing and the diagonal spacing of the base regions 108, is maintained in the semiconductor structure 300. It should further be noted that the first protective doped regions 408 and the second protective doped regions 602 may optionally include P+regions instead of P-base regions, depending on the desired electrical characteristics.

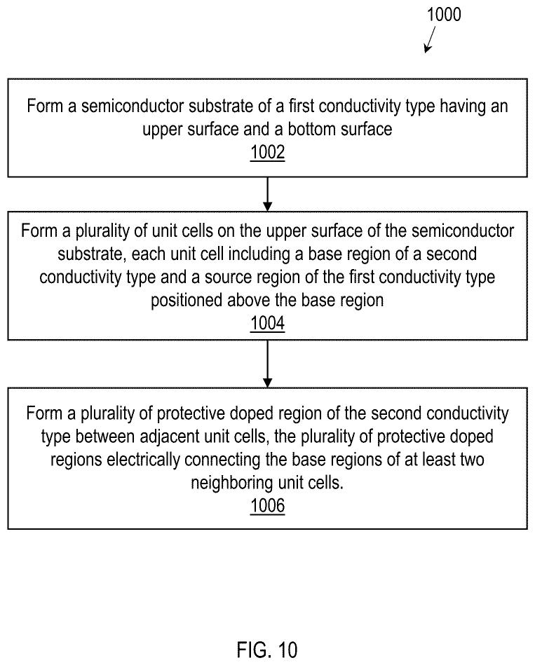

FIG. 10 is a flowchart 1000 depicting operational steps for the fabrication of a semiconductor structure with protective doped regions, according to an embodiment of the present disclosure.

The process starts at step 1002 by forming a semiconductor substrate of a first conductivity type having an upper surface and a bottom surface. In an embodiment, the semiconductor substrate includes a silicon carbide substrate.

The process continues at step 1004 by forming a plurality of unit cells on the upper surface of the semiconductor substrate, each unit cell including a base region of a second conductivity type, and a source region of the first conductivity type positioned above the base region.

The process ends at step 1006 by forming a plurality of protective doped regions of the second conductivity type. In one or more embodiments, the protective doped regions are positioned between adjacent unit cells for electrically connecting the base regions of at least two neighboring unit cells. In an embodiment, a protective doped region is formed above the source region and at each corner of the base region. In another embodiment, the plurality of protective doped regions extend between corner portions of the base region of at least three adjacent unit cells. In another embodiment, the plurality of protective doped regions are arranged in a geometric pattern that includes at least one of a triangular configuration or an octagonal configuration. In one or more embodiments, the plurality of protective doped regions are P-type base regions. In other embodiments, the plurality of protective doped regions are heavily doped P-type regions. In one or more embodiments, the plurality of protective doped regions extend between adjacent base regions of neighboring unit cells to form a continuous protective network that is defined by a patterning and implantation process associated with a P-base mask. The plurality of protective doped regions are configured to mitigate electric field concentrations and prevent floating of the base region.

In one or more embodiments, each of the plurality of unit cells further includes a drift region of the first conductivity type located on the upper surface of the semiconductor substrate, a JFET region located above the drift region, a channel region of the second conductivity type located within the base region, with the source region being adjacent to the channel region, a gate electrode located above the drift region via a gate oxide, the gate electrode surrounding the source region, a top metal layer above and electrically connected to the source region and the second protective doped region, and a bottom metal layer located on the bottom surface of the semiconductor substrate.

### EXAMPLES

Example 1. A semiconductor structure comprising:
a semiconductor substrate of a first conductivity type having an upper surface and a bottom surface, the semiconductor substrate including a silicon carbide substrate;
a plurality of unit cells disposed on the upper surface of the semiconductor substrate, each unit cell including:
   a base region of a second conductivity type, and
   a source region of the first conductivity type disposed above the base region; and
a plurality of protective doped regions of the second conductivity type, wherein:
   a first protective doped region is located above the source region of each unit cell, and
   a second protective doped region is located at a corner portion of at least two adjacent unit cells such that the second protective doped region partially extends above the corner portion of the at least two adjacent unit cells, wherein the second protective doped region electrically connects the base region of the two adjacent unit cells.

Example 2. The semiconductor structure according to Example 1, wherein the first protective doped region and the second protective doped region are configured to mitigate electric field concentrations and prevent floating of the base region.

Example 3. The semiconductor structure according to Example 1, wherein the first conductivity type is N-type and the second conductivity type is P-type.

Example 4. The semiconductor structure according to any of Example 1 or Example 3, wherein the first protective doped region and the second protective doped region comprise a heavily doped P-type region.

Example 5. The semiconductor structure according to Example 4, wherein an impurity concentration of the heavily doped P-type region is less than 1×10²¹ cm⁻³ and more than 1×10¹⁹ cm⁻³.

Example 6. The semiconductor structure according to any of Example 1or Example 3, wherein the first protective doped region and the second protective doped region comprise a P-type base region.

Example 7. The semiconductor structure according to claim 6, wherein an impurity concentration of the P-type base region is less 1×10²¹ cm⁻³ than and more than 1×10¹⁹ cm⁻³.

Example 8. The semiconductor structure according to claim 1, wherein each unit cell further comprises:
a drift region of the first conductivity type located on the upper surface of the semiconductor substrate;
a JFET region located above the drift region;
a channel region of the second conductivity type located within the base region, wherein the source region is adjacent to the channel region;
a gate electrode located above the drift region via a gate oxide, the gate electrode surrounding the source region;
a top metal layer above and electrically connected to the source region and the second protective doped region; and
a bottom metal layer located on the bottom surface of the semiconductor substrate.

Example 9. A semiconductor structure comprising:
a semiconductor substrate of a first conductivity type having an upper surface and a bottom surface, the semiconductor substrate including a silicon carbide substrate;
a plurality of unit cells disposed on the upper surface of the semiconductor substrate, each unit cell including:
   a base region of a second conductivity type, and
   a source region of the first conductivity type disposed above the base region; and
a plurality of protective doped regions of the second conductivity type, wherein the protective doped regions are positioned between at least two neighboring unit cells electrically connecting the base region of each of the at least two neighboring unit cells.

Example 10. The semiconductor structure according to Example 9, wherein the plurality of protective doped regions are configured to mitigate electric field concentrations and prevent floating of the base region.

Example 11. The semiconductor structure according to Example 9, wherein the plurality of protective doped regions extend between corner portions of the base region of at least three neighboring unit cells.

Example 12. The semiconductor structure according to Example 9, wherein the plurality of protective doped regions are arranged in a geometric pattern that includes triangular or octagonal configurations.

Example 13. The semiconductor structure according to Example 9, wherein the first conductivity type is N-type and the second conductivity type is P-type.

Example 14. The semiconductor structure according to any of Example 9 or Example 13, wherein the plurality of protective doped regions comprise heavily doped P-type regions.

Example 15. The semiconductor structure according to Example 14, wherein an impurity concentration of the heavily doped P-type regions is less than 1×10²¹ cm⁻³ and more than 1×10¹⁹ cm⁻³.

Example 16. The semiconductor structure according to any of Example 9 or Example 13, wherein the plurality of protective doped regions comprise P-type base regions.

Example 17. The semiconductor structure according to claim 16, wherein an impurity concentration of the P-type base regions is less 1×10²¹ cm⁻³ than and more than 1×10¹⁹ cm⁻³.

Example 18. The semiconductor structure according to Example 9, wherein each of the plurality of unit cells further comprises:
a drift region of the first conductivity type located on the upper surface of the semiconductor substrate;
a JFET region located above the drift region;
a channel region of the second conductivity type located within the base region, wherein the source region is adjacent to the channel region;
a gate electrode located above the drift region via a gate oxide, the gate electrode surrounding the source region;
a top metal layer above and electrically connected to the source region and the plurality of protective doped regions; and
a bottom metal layer located on the bottom surface of the semiconductor substrate.

### Example 19. a Semiconductor Structure Comprising:

a semiconductor substrate of a first conductivity type having an upper surface and a bottom surface, the semiconductor substrate including a silicon carbide substrate;
a plurality of unit cells disposed on the upper surface of the semiconductor substrate, each unit cell including:
   a base region of a second conductivity type, and
   a source region of the first conductivity type disposed above the base region; and
a plurality of protective doped regions of the second conductivity type, wherein the protective doped regions extend laterally between adjacent base regions of neighboring unit cells to form a continuous protective network arranged in a geometric pattern.

Example 20. The semiconductor structure according to Example 19, wherein the geometric pattern comprises at least one of a triangular or an octagonal configuration.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a semiconductor substrate of a first conductivity type having an upper surface and a bottom surface, the semiconductor substrate including a silicon carbide substrate;
a plurality of unit cells disposed on the upper surface of the semiconductor substrate, each unit cell including:
a base region of a second conductivity type, and
a source region of the first conductivity type disposed above the base region; and
a plurality of protective doped regions of the second conductivity type, wherein:
a first protective doped region is located above the source region of each unit cell, and
a second protective doped region is located at a corner portion of at least two adjacent unit cells such that the second protective doped region partially extends above the corner portion of at least two adjacent unit cells, wherein the second protective doped region electrically connects the base region of the at least two adjacent unit cells.

2. The semiconductor structure according to claim 1, wherein the first protective doped region and the second protective doped region are configured to mitigate electric field concentrations and prevent floating of the base region.

3. The semiconductor structure according to claim 1, wherein the first conductivity type is N-type and the second conductivity type is P-type.

4. The semiconductor structure according to claim 3, wherein the first protective doped region and the second protective doped region comprise a heavily doped P-type region.

5. The semiconductor structure according to claim 4, wherein an impurity concentration of the heavily doped P-type region is less than 1×10²¹ cm⁻³ and more than 1×10¹⁹ cm⁻³.

6. The semiconductor structure according to claim 3, wherein the first protective doped region and the second protective doped region comprise a P-type base region.

7. The semiconductor structure according to claim 6, wherein an impurity concentration of the P-type base region is less 1×10²¹ cm⁻³ than and more than 1×10¹⁹ cm⁻³.

8. The semiconductor structure according to claim 1, wherein each unit cell further comprises:
a drift region of the first conductivity type located on the upper surface of the semiconductor substrate;
a JFET region located above the drift region;
a channel region of the second conductivity type located within the base region, wherein the source region is adjacent to the channel region;
a gate electrode located above the drift region via a gate oxide, the gate electrode surrounding the source region;
a top metal layer above and electrically connected to the source region and the second protective doped region; and
a bottom metal layer located on the bottom surface of the semiconductor substrate.

9. A semiconductor structure comprising:
a semiconductor substrate of a first conductivity type having an upper surface and a bottom surface, the semiconductor substrate including a silicon carbide substrate;
a plurality of unit cells disposed on the upper surface of the semiconductor substrate, each unit cell including:
a base region of a second conductivity type, and
a source region of the first conductivity type disposed above the base region; and
a plurality of protective doped regions of the second conductivity type, wherein each protective doped region is positioned between at least two neighboring unit cells electrically connecting the base region of each of the at least two neighboring unit cells.

10. The semiconductor structure according to claim 9, wherein a diagonal spacing between a protective doped region and a corner portion of the base region of a neighboring unit cell is less than a vertical spacing between the base region of the at least two neighboring unit cells.

11. The semiconductor structure according to claim 9, wherein the plurality of protective doped regions extends between corner portions of the base region of at least three neighboring unit cells.

12. The semiconductor structure according to claim 9, wherein the plurality of protective doped regions is arranged in a geometric pattern that includes triangular or octagonal configurations.

13. The semiconductor structure according to claim 9, wherein the first conductivity type is N-type and the second conductivity type is P-type.

14. The semiconductor structure according to claim 13, wherein the plurality of protective doped regions comprises heavily doped P-type regions.

15. The semiconductor structure according to claim 14, wherein an impurity concentration of the heavily doped P-type regions is less than 1×10²¹ cm⁻³ and more than 1×10¹⁹ cm⁻³.

16. The semiconductor structure according to claim 13, wherein the plurality of protective doped regions comprises P-type base regions.

17. The semiconductor structure according to claim 16, wherein an impurity concentration of the P-type base regions is less 1×10²¹ cm⁻³ than and more than 1×10¹⁹ cm⁻³.

18. The semiconductor structure according to claim 9, wherein each of the plurality of unit cells further comprises:
a drift region of the first conductivity type located on the upper surface of the semiconductor substrate;
a JFET region located above the drift region;
a channel region of the second conductivity type located within the base region, wherein the source region is adjacent to the channel region;
a gate electrode located above the drift region via a gate oxide, the gate electrode surrounding the source region;
a top metal layer above and electrically connected to the source region and each of the plurality of protective doped regions; and
a bottom metal layer located on the bottom surface of the semiconductor substrate.

19. A semiconductor structure comprising:
a semiconductor substrate of a first conductivity type having an upper surface and a bottom surface, the semiconductor substrate including a silicon carbide substrate;
a plurality of unit cells disposed on the upper surface of the semiconductor substrate, each unit cell including:
a base region of a second conductivity type, and
a source region of the first conductivity type disposed above the base region; and
a plurality of protective doped regions of the second conductivity type, wherein the protective doped regions extend laterally between adjacent base regions of neighboring unit cells to form a continuous protective network arranged in a geometric pattern.

20. The semiconductor structure according to claim 19, wherein the geometric pattern comprises at least one of a triangular or an octagonal configuration.
